(19) United States
(12) Patent Application Publication
(10) Pub. No.: US 2026/0118407 A1
(43) Pub. Date: Apr. 30, 2026

(54) INTEGRATED ACTIVE COOLING SOLUTION FOR DEVICES MOUNTED ON MULTILAYER ORGANIC SUBSTRATES ON PROBE CARD ASSEMBLIES

(71) Applicant: Teradyne, Inc., North Reading, MA (US)

(72) Inventors: Kevin A. Thompson, Thousand Oaks, CA (US); Luis Antonio Valiente, Dracut, MA (US); Marie Stauffer, North Reading, MA (US); Geng Qian, North Reading, MA (US)

(73) Assignee: Teradyne, Inc., North Reading, MA (US)

(21) Appl. No.: 19/372,186

(22) Filed: Oct. 28, 2025

Related U.S. Application Data
(60) Provisional application No. 63/713,559, filed on Oct. 29, 2024.

(51) Int. Cl. G01R 31/28; G01K 3/00; G01R 1/073; H05K 1/02; H05K 1/03

(52) U.S. Cl. CPC G01R 31/2834; G01K 3/005; G01R 1/07342; H05K 1/0203; H05K 1/0313; H05K 2201/064; H05K 2201/10151

(57) ABSTRACT

An automatic test equipment (ATE) system having active thermal management. The ATE system includes a probe card having a first side and a second side, a substrate mounted to the second side of the probe card, a device mounted to the substrate, probe needles mounted the substrate, and an active thermal management system, including: a thermal management component passing through the probe card and thermally coupled to the device, and an active cooling system thermally coupled to the thermal management component at the first side of the probe card.

### RELATED APPLICATIONS

This application claims the priority benefit under 35 U.S.C. § 119(e) to U.S. Provisional Application No. 63/713,559, filed on Oct. 29, 2024, entitled “INTEGRATED ACTIVE COOLING SOLUTION FOR DEVICES MOUNTED ON MULTILAYER ORGANIC SUBSTRATES ON PROBE CARD ASSEMBLIES”, which is herein incorporated by reference in its entirety.

### BACKGROUND

### Field

The present technology relates to thermal management of devices in an automated test equipment setting.

### BRIEF SUMMARY

According to aspects of the disclosure, there is provided an automatic test equipment (ATE) system. Some embodiments provide for an automatic test equipment (ATE) system comprising: a probe card having a first side and a second side; a device substrate mounted to the second side of the probe card; a first electronic tester device mounted to the substrate opposite the probe card; probe needles mounted the device substrate; and an active thermal management system, comprising: a first thermal management component passing at least partially through the probe card and thermally coupled to the first electronic tester device; and an active cooling system thermally coupled to the first thermal management component proximate the first side of the probe card.

In some embodiments, the device substrate is a multilayer organic (MLO) substrate.

In some embodiments, the first electronic tester device comprises high bandwidth memory (HBM).

In some embodiments, the active cooling system comprises a liquid cooling system thermally coupled to the first thermal management component, the liquid cooling system configured to circulate a liquid coolant adjacent the first thermal management component.

In some embodiments, the liquid cooling system is directly coupled to the first thermal management component, such that the coolant circulates through the first thermal management component.

In some embodiments, the ATE system further comprises: a cold plate mounted to the first side of the probe card, and thermally coupled to the first thermal management component, wherein the liquid cooling system is configured to circulate the liquid coolant through the cold plate.

In some embodiments, the active cooling system further comprises one or more impingement jets configured to direct a stream of air toward the first thermal management component at the first side of the probe card.

In some embodiments, the ATE system further comprises: a second electronic tester device mounted to the substrate, wherein: the active thermal management system further comprises: a second thermal management component passing at least partially through the probe card and thermally coupled to the second electronic tester device; and the active cooling system is thermally coupled to the second thermal management component proximate the first side of the probe card.

In some embodiments, the ATE system further comprises: a temperature sensor configured to monitor a temperature of the first thermal management component and/or the first electronic tester device.

In some embodiments, the ATE system further comprises: a controller communicatively coupled to the active thermal management system and the temperature sensor, the controller configured to activate the active thermal management system when the temperature of the first thermal management component and/or the first electronic tester device exceeds a threshold temperature.

Some embodiments provide for an automated test equipment (ATE) system, comprising: a probe card having a first side and a second side; a device substrate mounted to the second side of the probe card; a first electronic tester device mounted to the substrate; probe needles mounted the substrate; and an active thermal management system, comprising: a cold plate mounted to the first side of the probe card; a liquid cooling system coupled to the cold plate and configured to circulate a liquid coolant through the cold plate; and a first thermal management component thermally coupled to the cold plate and to the first electronic tester device.

In some embodiments, the device substrate is a multilayer organic (MLO) substrate.

In some embodiments, the first electronic tester device comprises high bandwidth memory (HBM).

In some embodiments the ATE system further comprises: a fastener passing through the first thermal management component and securing the first thermal management component to the probe card.

In some embodiments, the ATE system further comprises: a first thermal interface material positioned between, and thermally coupling, the cold plate and the first thermal management component; and a second thermal interface material positioned between, and thermally coupling, the first thermal management component and the first electronic tester device.

In some embodiments, the first and second thermal interface materials comprise gap filler materials.

In some embodiments, the second thermal interface material has a lower durometer than the first thermal interface material.

Some embodiments provide for a method for performing automated testing of a device under test (DUT) using an automated test equipment (ATE) system comprising: a probe card having a first side and a second side, a device substrate mounted to the second side of the probe card, a first electronic tester device mounted to the device substrate, probe needles mounted the device substrate, a temperature sensor, and an active thermal management system thermally coupled to the first electronic tester device, the method comprising: electrically connecting the ATE system to the DUT via the probe needles of the ATE system; performing automated testing of the DUT by transmitting electrical signals to the DUT via the probe needles of the ATE system; during the automated testing of the DUT, actively cooling the first electronic tester device of the ATE system using the active thermal management system.

In some embodiments, actively cooling the first electronic tester device comprises: using the temperature sensor to monitor a temperature indicative of the temperature of the first electronic tester device of the ATE system; and when the temperature exceeds a first threshold temperature, activating the active thermal management system to cool the first electronic tester device of the ATE system.

In some embodiments, actively cooling the first electronic tester device further comprises: when the temperature is less than a second threshold temperature, lower than the first threshold temperature, stopping the active cooling of the first device of the ATE system.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1A is a side view of an example ATE system, according to some embodiments of the technology described herein.

FIG. 1B is a top view of the example ATE system of FIG. 1A, according to some embodiments of the technology described herein.

FIG. 2 shows an example ATE system having an active thermal management system including a cold plate, according to some embodiments of the technology described herein.

FIG. 3A is a perspective view of an example ATE system with internal routing of coolant lines, according to some embodiments of the technology described herein.

FIG. 3B is a perspective view of the example ATE system of FIG. 3A with the probe card removed, according to some embodiments of the technology described herein.

FIG. 3C is a sectional view of the example ATE system of FIGS. 3A-3B showing coolant routing through the test head of a tester, according to some embodiments of the technology described herein.

FIG. 3D is a sectional view of the example ATE system of FIGS. 3A-3B showing coolant routing through an instrument of a tester, according to some embodiments of the technology described herein.

FIG. 4 shows an alternative example ATE system having an air impingement thermal management system, according to some embodiments of the technology described herein.

FIG. 5 shows an alternative example ATE system having liquid cold plates passing through the probe card, according to some embodiments of the technology described herein.

FIG. 6 is an example process that may be performed by an ATE system to facilitate cooling components of the ATE system, according to some embodiments of the technology described herein.

### DETAILED DESCRIPTION

Automatic test equipment (ATE) systems may be used for the testing of one or more devices under test (DUTs). ATE systems may include components for performing testing of DUTs, for example: testers which include circuitry, processors and memory for testing the functions of the DUTs; a probe card or device interface board (DIB) supporting the electronic tester; devices mounted on the probe card; and connection components for connecting the tester to the one or more DUTs. In some embodiments, the electronic tester devices may include high bandwidth memory devices (HBM) such as HBM3 memory, among other devices used in testing DUTs such as integrated circuits, processors, microcontrollers or other devices. In some embodiments, connection components may include probe needles or a socket for interfacing with a DUT, among other suitable connection techniques.

In some embodiments, one or more components may be connected to the probe card via a substrate, for example, electronic tester devices and/or connection components may be connected to the probe card via a substrate. Such substrates may be used for improved electronic performance, for example by providing improved signal stability across a greater range of frequencies, and for high density connections. Such substrates may include multilayer organic (MLO) substrates, thin-film substrates, printed circuit boards (PCBs), glass substrates, and/or ceramic substrates, among other suitable substrates.

Current trends in circuit design involve greater power for testing DUTs. For example, devices used in testing, such as HBMs, operate at increasing power levels to perform the functions necessary for testing DUTs. Thus, such devices may generate large amounts of heat. Thermal management is important to ensure optimal performance of the ATE system. Improper thermal management can lead to overheating of components, component failure, and worsened performance of ATE system.

Thermal management is additionally important in ATE systems having components mounted on substrates such as MLOs or other substrates described herein. Such substrates have poor thermal conductivity and therefore limit the cooling of components mounted to them.

Accordingly, the inventors have recognized the importance of thermal management in ATE systems and have developed ATE systems having thermal management systems integrated therein.

In some embodiments, ATE are provided having active cooling systems for components. In some embodiments active thermal management systems comprise liquid cooling systems and air cooling systems.

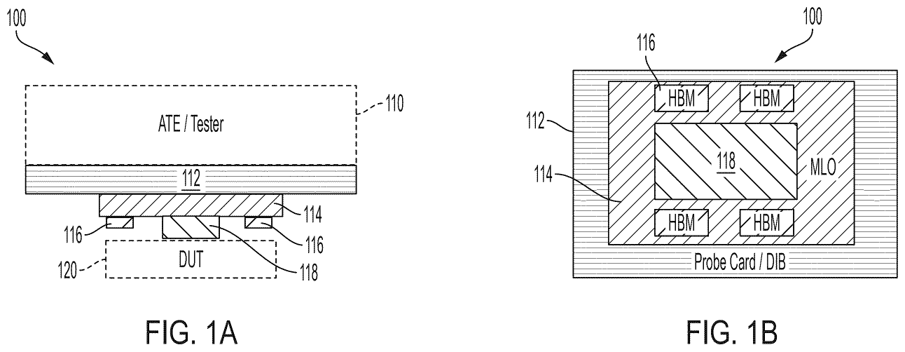

FIGS. 1A-1B show an example ATE system with probe card configuration, according to some embodiments of the technology described herein. FIG. 1A is a side view of an example ATE system 100. System 100 includes tester 110, probe card 112, substrate 114, electronic tester devices 116, and probe needles 118. The system 100 connects to device under test (DUT) 120, via probe needles to perform automated testing of the DUT 120 to ensure proper performance. DUT 120 may be any device, for example a microcontroller, printed circuit board (PCB), a central processing unit, a graphic processing unit, a solid state drive, a power supply unit, an integrated circuit, a RF module, or any other suitable device.

Tester 110 includes circuity and processing components for verifying the functionality of DUT 120. The tester 110 is connected to a first side of the probe card 112. The probe card 112 provides an interface between the components of the tester 110 and the substrate 114. The probe card may electrically connect components of the tester 110 to the substrate 114.

Substrate 114 is connected to a second side of probe card 112, opposite the tester 110. Substrate 114 may support various components that are used in the automated testing of the DUT 120. Substrate 114 may be any suitable substrate, for example a multilayer organic (MLO) substrate, a thin-film substrate, a PCB, a glass substrate, and/or a ceramic substrate, among other suitable substrates. As shown, substrate 114 supports electronic tester devices 116 and probe needles 118.

Electronic tester devices 116 may be any devices used to support the testing of the DUT 120, for example, electronic tester devices 116 may be high bandwidth memory devices (HBM) such as HBM3 memory or other devices used in testing DUTs, such as integrated circuits, processors, microcontrollers or other devices.

Substrate 114 additionally supports probe needles 118. Probe needles 118 may be electrically connected to one or more of the: electronic tester devices 116, other components of the substrate 114, components of the probe card 112 and/or components of the tester 110. During an automated test procedure, the ATE system 100 may engage with the DUT 120 (e.g., by moving the ATE system 100 or portions thereof toward the DUT 120 and/or by moving the DUT 120 toward the ATE system 100). The probe needles 118 may electrically connect to one or more portions of the DUT 120, and electrical signals may be provided to the DUT 120 via the probe needles 118 to confirm functionality of the DUT 120. In some embodiments, the ATE system may include one or more sockets for electrically connecting to portions of the DUT 120, in place of, or in addition to, probe needles 118.

FIG. 1B is a top view of the ATE system 100. As shown, the connection components, shown as probe needles 118, are positioned at the center of the ATE system 100, on substrate 114. The substrate 114 additionally supports four devices 116, which surround the probe needles 118. While substrate 114 is shown as an MLO substrate, substrate 114 may be a different type of substrate, for a thin-film substrate, a PCB, a glass substrate, and/or a ceramic substrate, among other suitable substrates. The devices 116 are shown as HBMs, but other devices may be used, as described herein, such as integrated circuits, processors, microcontrollers or other devices. In some embodiments greater or fewer devices may be included, for example 1 device, 2 devices, 3 devices, 5 devices, between 5 and 10 devices and/or greater than 10 devices. The probe needles 118 and devices 116 are mounted on the substrate 114, which is mounted on the probe card 112.

As described above, the inventors have appreciated that current trends in circuit design have required the development of new ATE systems, such as described with reference to FIGS. 1A-B, utilizing MLO or similar substrates for improved signal stability and high density connections, and HBMs or other high power draw devices for testing of DUTs. MLO substrates and similar substrates are poor thermal conductors and limit cooling of devices mounted thereon, and HBMs and other devices generate large amounts of heat. Accordingly, the inventors have developed thermal management systems for use with such new ATE systems, which provide cooling for electronic tester devices, such as HBMs during automated testing.

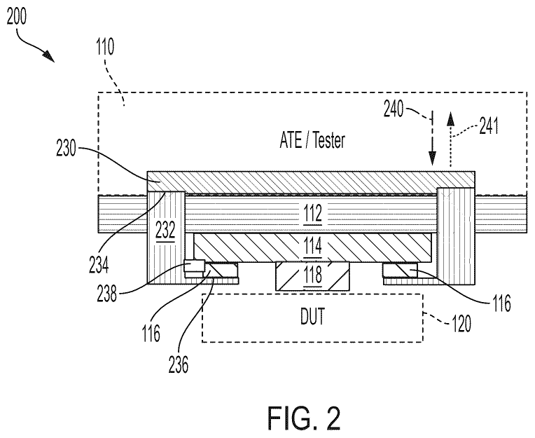

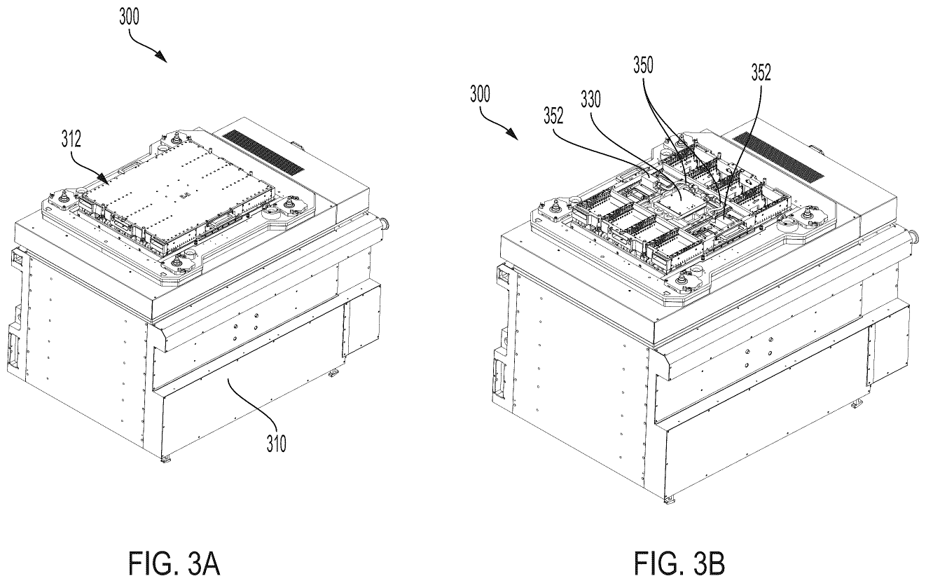

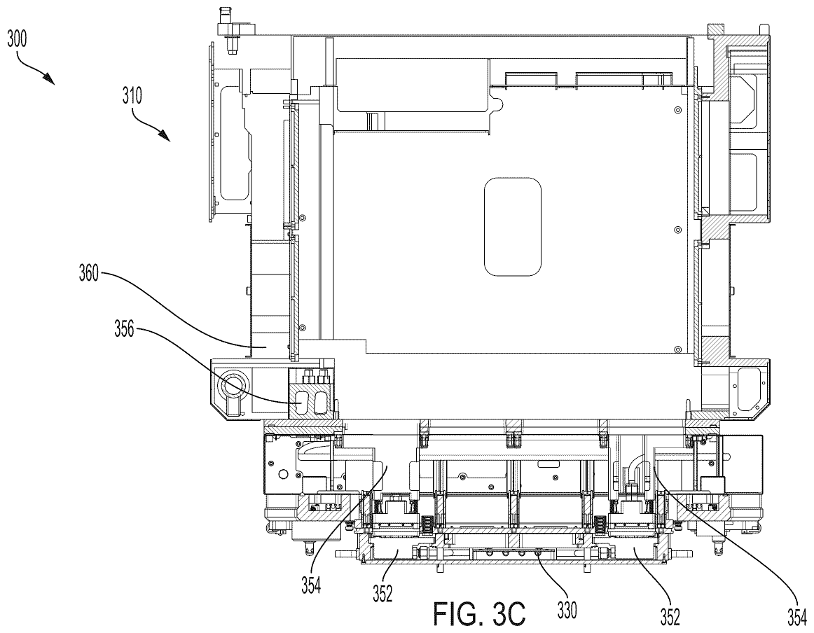

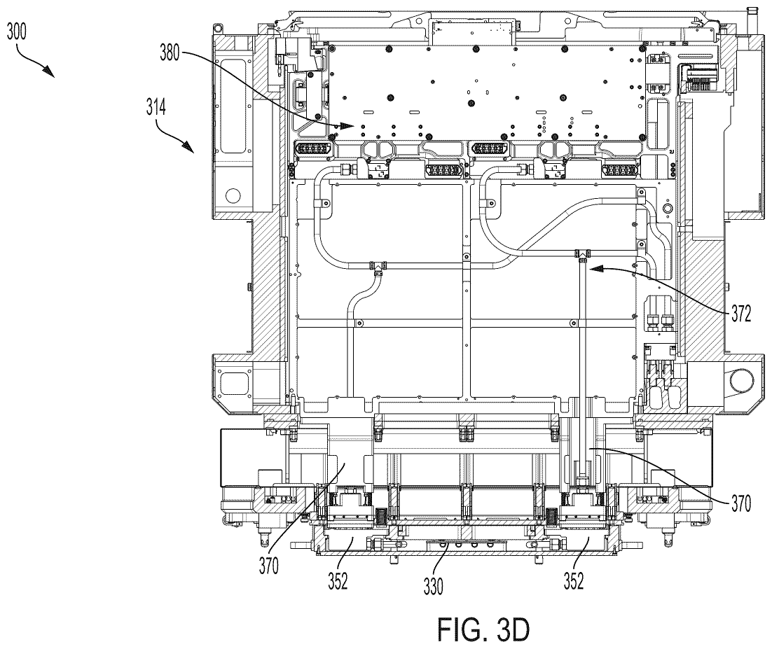

FIGS. 2-3D show an example of a preferred embodiment of an ATE system with an active thermal management system. FIG. 2 shows an example ATE system having an active thermal management system including a cold plate, according to some embodiments of the technology described herein. The ATE system 200 includes some components shared with ATE system 100, described with reference to FIGS. 1A-B, and like reference numerals are used for such components.

The active thermal management system of ATE system 200 include cold plate 230, heat spreaders 232, coolant supply 240, coolant return 241, and temperature sensor 238.

The cold plate 230 is mounted to the same side of probe card 112 as the tester 110. The cold plate 230 may include internal structures such as channels for facilitating liquid cooling. The internal structures may allow for the flowing of cooled liquid coolant to and removal of heated liquid coolant from the cold plate 230. For example, the cold plate 230 may be any suitable liquid cold plate, for example a tubed cold plate, a channeled cold plate, a serpentine cold plate, a parallel channel cold plate, an embedded pin cold plate, or any other suitable cold plate. The cold plate is dimensioned to fit within the ATE system 200 and may have a length and width between 10-20 cm, and a thickness between 10-50 mm.

The cold plate 230 is coupled to a heat exchanger, via coolant supply 240 and coolant return 241. The coolant supply 240 provides cooled liquid coolant to the cold plate and the coolant return 241 returns warm coolant to the heat exchanger. The heat exchanger may then cool the warmed coolant and recirculate the coolant to the cold plate 230. The coolant may be any suitable liquid coolant, for example a Hydrofluoroethers (HFE) coolant, deionized water, water-glycol mixtures, among other coolants. Coolant supply 240 and coolant return 241 may be routed through tester 110, such as described with reference to FIGS. 3A-D. The heat exchanger may be incorporated within tester 110 or may be external to tester 110.

The cold plate is thermally coupled to the heat spreaders 232, and functions to cool/remove heat from the heat spreaders 232. As shown, there are two heat spreaders 232, however ATE system 200 may include any number of heat spreaders, for example one heat spreader, three heat spreaders, four heat spreaders, five heat spreaders, or greater than five heat spreaders. The heat spreaders 232 may include high conductivity materials (e.g., copper, other metals, graphene, and/or composite materials), heat pipes, and/or vacuum chambers, among other suitable designs. Heat spreaders 232 may be coupled to the probe card via one or more fasteners passing through a portion of the heat spreaders 232 and securing the heat spreaders to the probe card.

The heat spreaders 232 pass through the probe card 112 and are thermally coupled to the electronic tester devices 116. In some embodiments, the heat spreaders 232 may pass through the substrate 114 and/or other layers or components of the ATE system 200. The probe card and/or substrate and/or other layers or components may include holes or openings for the heat spreaders to pass through. In some embodiments, the heat spreaders 232 may pass partially through the probe card 112 and/or other components.

Each heat spreader may be thermally coupled to a single electronic tester device or may be coupled to multiple electronic tester devices. During operation of ATE system 200, the heat spreaders cool the electronic tester devices 116 by removing heat from the devices 116 and transferring the heat to the cold plate 230. The heat spreaders 232, therefore alleviate the excess heat dissipated from the high-power functions used in testing and optimizing performance of the automated tester.

The thermal conductivity between the heat spreaders 232 and the cold plate 230 and electronic tester devices 116 may be increased via a thermal coupling material. For example, a thermal coupling material may be provided at the thermal interface 234 between the cold plate 230 and heat spreaders 232 and at the thermal interface 236 between the heat spreaders 232 and the electronic tester devices 116. Any suitable thermal coupling material may be used, for example thermal paste, thermal epoxy, thermal pads, gap filler material, phase change material, thermal adhesives, among other suitable thermal coupling materials. Different thermal coupling materials may be used at the interfaces 234 and 236. For example, a thermal coupling material with a higher thermal conductivity may be used at interface 236 because there is a smaller contact area between the heat spreaders 232 and the electronic tester devices 116 (e.g., a material with 3 W/mK conductivity may be used at interface 234 and a material with a 10 W/mK conductivity may be used at interface 236). Further, the materials at the interfaces 234 and 236 may have different physical properties. For example, a soft thermal coupling material (e.g., a material with a low durometer) may be used at interface 236 to prevent damage to the electronic tester devices 116 during assembly (e.g., such as from compressive forces between the heat spreaders 232 and the electronic tester devices 116).

The active thermal management system additionally include temperature sensor 238. The temperature sensor may directly measure the temperature of the electronic tester devices 116. Alternatively, the temperature sensor 238 may monitor a temperature indicative of the temperature of the electronic tester devices 116, for example a temperature of the heat spreaders 232, a temperature at the interface 234, an air temperature adjacent the electronic tester devices 116, and/or a temperature of the coolant within the cold plate 230.

A controller (not pictured) may be connected to the temperature sensor 238 and may control the active thermal management system based on the temperature sensor. For example, when the temperature at the temperature sensor 238 exceeds a threshold temperature, the active thermal management system may activate to cool the devices 116, and/or when the temperature drops below a threshold temperature the active thermal management system may stop active cooling. Alternatively, the ATE system 200 may not include a temperature sensor and the active thermal management system may always be operating during automated testing.

FIGS. 3A-D show an example ATE system having an active thermal management system with a liquid cold plate and coolant supply running through the tester, according to some embodiments of the technology described herein. ATE system 300 may be used in a configuration, such as shown with reference to FIG. 2. FIG. 3A is a perspective view of ATE system 300. ATE system 300 includes probe card 312 and tester 310, which may be configured as described herein.

FIG. 3B is a perspective view of the ATE system 300 with the probe card removed, to reveal components of an active thermal management system. Visible are the cold plate 330, coolant lines 350 and fluid interconnects 352. The cold plate 330 is a fluid cold plate and is mounted to the probe card. The coolant lines 350 supply coolant between a heat exchanger and the cold plate, as described herein. The fluid interconnects 352 connect the coolant lines 350 to additional coolant routing contained within the tester 310. The fluid interconnects 352 may be blind-mate interconnections, such that when the probe card (with the cold plate 330 and fluid interconnects 352 mounted thereon) is attached to the tester, the connection between the fluid interconnects 352 and the coolant routing within tester 310 is automatically formed.

The routing of coolant lines within an ATE system can take different forms. FIGS. 3C-D show examples of coolant routing within a tester, according to some embodiments of the technology described herein. FIG. 3C is a sectional view of the ATE system 300 of FIGS. 3A-B. FIG. 3C shows an example of coolant routing through the test head 360 of tester 310. As shown, the fluid interconnects 352 are connected to brackets 354 extending from the tester 310. The connection between the fluid interconnects 352 and the brackets 354 may be a blind-mate quick disconnect connection. The brackets 354 fluidically connect the fluid interconnects 352 to the coolant lines 356 which are routed through the test head 360 of the tester 310. The coolant lines 356 may connect to a heat exchanger, as described herein, to provide coolant to cold plate 330.

FIG. 3D is a sectional view of the example ATE system of FIGS. 3A-B showing coolant routing through an instrument 380 of tester 314. FIG. Tester 314 may be used in place of tester 310 in FIGS. 3A-B. As shown, the fluid interconnects 352 are connected to quick disconnect towers 370 extending from the instrument 380 of the tester 314. The connection between the fluid interconnects 352 and the quick disconnect towers 370 is a blind-mate quick disconnect connection. The quick disconnect towers 370 fluidically connect the fluid interconnects 352 to the coolant lines 372 which are routed through the instrument 380 of the tester 314. The coolant lines 372 may connect to a heat exchanger, as described herein, to provide coolant to cold plate 330.

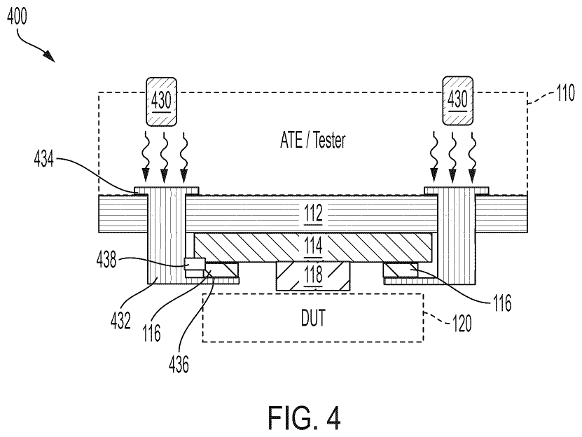

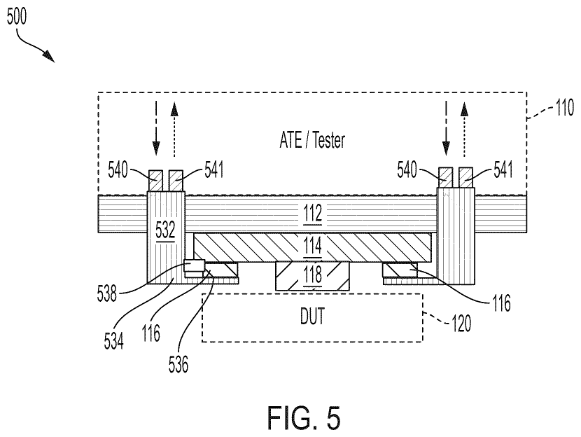

FIGS. 4-5 show alternate embodiments of ATE systems with an active thermal management system, according to some embodiments of the technology described herein.

FIG. 4 shows an alternative example ATE system having an air impingement thermal management system, according to some embodiments of the technology described herein. Such a configuration may be used for ATE systems which require a lower level of cooling, for example systems with fewer high power electronic tester devices or systems with lower power draws. The ATE system 400 includes some components shared with ATE system 100, described with reference to FIGS. 1A-B, and like reference numerals are used for such components. The ATE system 400 includes an active thermal management system including air impingement jets 430, heat spreaders 432, and temperature sensor 438.

The heat spreaders 432 pass through the probe card 112 to contact the electronic tester devices 116. The heat spreaders 432 may be made of thermally conductive materials, as described herein. While two heat spreaders are shown, the ATE system may include greater or fewer heat spreaders, as described herein.

The surface 434 of heat spreaders 432 is exposed on the side of the probe card 112 facing the tester 110. The air impingement jets 430 may direct a stream of air at the surface 434 of the heat spreaders to cool the heat spreaders. In some embodiments, the impingement jet may supply a stream of an inert gas such as nitrogen. While two air impingement jets 430 are shown, any number of air impingement jets may be used. For example, each heat spreader may have one or more air impingement jets directed at its exposed surface.

The surface 434 may have one or more features to improve cooling via the air impingement jets 430. For example, the surface 434 may have fins, blades channels, and/or a surface texture, among other features, to improve cooling from the air impingement jets 430.

The heat spreaders 432 thermally couple to the electronic tester devices 116 to cool the electronic tester devices during use of the ATE system. The interfaces 436 between the heat spreaders 432 and the electronic tester devices 116 may include a thermal coupling material to improve the thermal connection, as described herein.

ATE system 400 additionally includes temperature sensor 438, which may sense a temperature indicative of that of the electronic tester devices. The air impingement jets 430 may be controlled based on the temperature sensed by the temperature sensor 438, as described herein.

FIG. 5 shows an alternative example ATE system having liquid cold plates passing through the probe card, according to some embodiments of the technology described herein. Such a configuration may be used for ATE systems which require a higher level of cooling, for example systems with a large number of high power electronic tester devices or systems with high power draws. The ATE system 500 includes some components shared with ATE system 100, described with reference to FIGS. 1A-B, and like reference numerals are used for such components.

The ATE system 500 includes an active thermal management system including liquid cold plates 532 and temperature sensor 538. The liquid cold plates 532 pass through the probe card 112, and are connected via heat spreaders 534 to the electronic tester devices 116. While two liquid cold plates 532 are shown, the ATE system may include greater or fewer liquid cold plates which are used to cool electronic tester devices, such as described herein with reference to heat spreaders 232. The liquid cold plates 532 may be made of a thermally conductive material, and may include internal features (e.g., channels, tubing, etc.) for facilitating heat transfer between coolant and the heat spreaders 534.

Coolant is circulated through the liquid cold plates 532 via coolant supply 540 and coolant return 541. The coolant supply 540 and coolant return 541 may be routed through the tester 110, such as described with reference to FIGS. 3A-D.

The heat spreaders may be made of a thermally conductive material, as described herein, to facilitate heat transfer between the electronic tester devices 116, and provide cooling to the electronic tester devices 116 during operation of the ATE system 100. The interface 536 between the heat spreaders 534 and the electronic tester devices 116 may include a thermal coupling material, as described herein.

ATE system 500 additionally includes temperature sensor 538, which may sense a temperature indicative of that of the electronic tester devices 116, as described herein. The liquid cold plates 532 may be controlled based on the temperature sensed by the temperature sensor 538, as described herein.

The ATE systems as described herein with reference to FIGS. 2-5 provide cooling to devices, such as HBM. Components of the ATE systems described with reference to FIGS. 2-5 may be used in combination with each other. For example, multiple cooling methodologies may be used in combination with each other. Such cooling improves performance of ATE components, avoids component overheating and component failure due to overheating, and allows for testing of DUTs using high power devices without reduced performance.

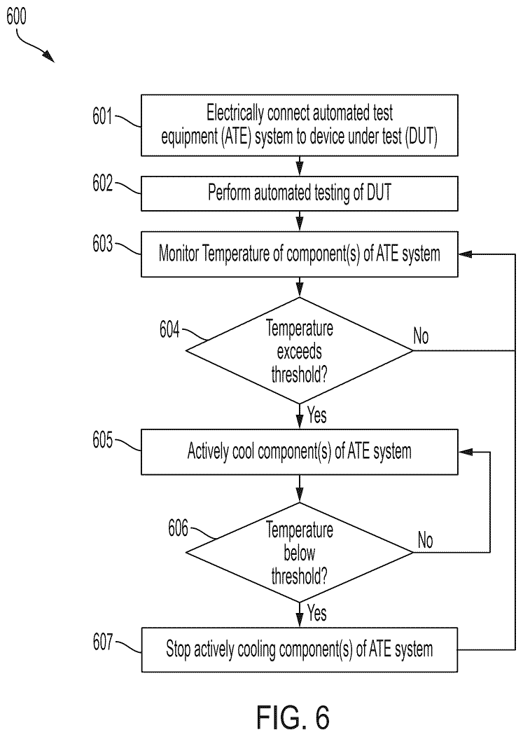

FIG. 6 is an example process that may be performed by an ATE system to facilitate cooling components of the ATE system, according to some embodiments of the technology described herein. Process 600 may be performed using one or more components of an ATE system as described herein, for example using one or more processors and/or controllers among other components.

Process 600 begins with act 601, in which the ATE system is electrically connected to a DUT. The ATE system may be electrically connected to a DUT, via probe needles and/or sockets, as described herein.

Process 600 then proceeds to act 602, in which automated testing of the DUT is performed. Automated testing of the DUT may involve sending electrical signals from the ATE to the DUT, and monitoring the response of the DUT to ensure proper functionality.

Process 600 then proceeds to acts 603-607, which involve actively cooling components of the ATE system and may be performed concurrently with act 602. In act 603, the temperature of components of the ATE system are monitored. Such components may include electronic tester devices, such as those described herein. The temperatures may be monitored via one or more temperature sensors contained within the ATE system. The temperature sensors may directly measure the temperature of electronic tester devices and/or may measure the temperature indicative of that of the electronic tester devices, as described herein.

At act 604, it is determined whether the temperature monitored in act 603 exceeds a threshold temperature. The threshold temperature may be a temperature at or below the temperature at which the performance of the ATE system and/or components of the ATE system is compromised due to overheating. If it is determined at act 604 that the temperature of the components of the ATE system do not exceed the threshold temperature, then the process returns to act 603 and the temperature of the components of the ATE system continues to be monitored. If it is determined that the temperature of the components of the ATE system exceeds a threshold temperature, process 600 proceeds to act 605.

At act 605 the components of the ATE system are actively cooled. Act 605 may involve cooling the components of the ATE system as described herein, such as described with reference to FIGS. 2-5. For example, act 605 may involve supplying coolant to a cold plate of an ATE system, such as described with reference to FIGS. 2-3D and 5. Alternatively, act 605 may involve activating air impingement jets, such as described with reference to FIG. 5.

The temperature of the components of the ATE system may continue to be monitored after act 605. At act 606 it is determined whether the temperature of the components of the ATE system is below a threshold temperature. The threshold temperature may be lower than that described with reference to act 604, and may be a temperature at which the components of the DUT are sufficiently cooled to ensure proper functionality. If it is determined at act 606 that the temperature of the components of the ATE system is not below the threshold temperature, process 600 returns to act 605 to continue active cooling of the components of the ATE system. If it is determined that the temperature of the components of the ATE system is below the threshold temperature, process 600 proceeds to act 607.

At act 607, the active cooling of the components of the ATE system is stopped. For example, the ATE system may stop supplying coolant to a cold plate and/or may stop cooling coolant. Alternatively, impingement jets may no longer supply air to cool components of the ATE system. After act 607, process 600 returns to act 603 to monitor the temperature of component of the ATE system.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having described above several aspects of at least one embodiment, it is appreciated that various alterations, modifications, and improvements will readily occur to those skilled in the art. Such alterations, modifications, and improvements are intended to be object of this disclosure. Accordingly, the foregoing description and drawings are by way of example only.

What is claimed is:

1. An automatic test equipment (ATE) system comprising:
a probe card having a first side and a second side;
a device substrate mounted to the second side of the probe card;
a first electronic tester device mounted to the substrate opposite the probe card;
probe needles mounted the device substrate; and
an active thermal management system, comprising:
a first thermal management component passing at least partially through the probe card and thermally coupled to the first electronic tester device; and
an active cooling system thermally coupled to the first thermal management component proximate the first side of the probe card.

2. The ATE system of claim 1, wherein the device substrate is a multilayer organic (MLO) substrate.

3. The ATE system of claim 1, wherein the first electronic tester device comprises high bandwidth memory (HBM).

4. The ATE system of claim 1, wherein the active cooling system comprises a liquid cooling system thermally coupled to the first thermal management component, the liquid cooling system configured to circulate a liquid coolant adjacent the first thermal management component.

5. The ATE system of claim 4, wherein the liquid cooling system is directly coupled to the first thermal management component, such that the coolant circulates through the first thermal management component.

6. The ATE system of claim 4, further comprising:
a cold plate mounted to the first side of the probe card, and thermally coupled to the first thermal management component, wherein the liquid cooling system is configured to circulate the liquid coolant through the cold plate.

7. The ATE system of claim 1, wherein the active cooling system comprises one or more impingement jets configured to direct a stream of air toward the first thermal management component at the first side of the probe card.

8. The ATE system of claim 1, further comprising:
a second electronic tester device mounted to the substrate, wherein:
the active thermal management system further comprises:
a second thermal management component passing at least partially through the probe card and thermally coupled to the second electronic tester device; and
the active cooling system is thermally coupled to the second thermal management component proximate the first side of the probe card.

9. The ATE system of claim 1, further comprising:
a temperature sensor configured to monitor a temperature of the first thermal management component and/or the first electronic tester device.

10. The ATE system of claim 9, further comprising:
a controller communicatively coupled to the active thermal management system and the temperature sensor, the controller configured to activate the active thermal management system when the temperature of the first thermal management component and/or the first electronic tester device exceeds a threshold temperature.

11. An automated test equipment (ATE) system, comprising:
a probe card having a first side and a second side;
a device substrate mounted to the second side of the probe card;
a first electronic tester device mounted to the substrate;
probe needles mounted the substrate; and
an active thermal management system, comprising:
a cold plate mounted to the first side of the probe card;
a liquid cooling system coupled to the cold plate and configured to circulate a liquid coolant through the cold plate; and
a first thermal management component thermally coupled to the cold plate and to the first electronic tester device.

12. The ATE system of claim 11, wherein the device substrate is a multilayer organic (MLO) substrate.

13. The ATE system of claim 11, wherein the first electronic tester device comprises high bandwidth memory (HBM).

14. The ATE system of claim 11, further comprising:
a fastener passing through the first thermal management component and securing the first thermal management component to the probe card.

15. The ATE system of claim 11, further comprising:
a first thermal interface material positioned between, and thermally coupling, the cold plate and the first thermal management component; and
a second thermal interface material positioned between, and thermally coupling, the first thermal management component and the first electronic tester device.

16. The ATE system of claim 15, wherein the first and second thermal interface materials comprise gap filler materials.

17. The ATE system of claim 15, wherein the second thermal interface material has a lower durometer than the first thermal interface material.

18. A method for performing automated testing of a device under test (DUT) using an automated test equipment (ATE) system comprising: a probe card having a first side and a second side, a device substrate mounted to the second side of the probe card, a first electronic tester device mounted to the device substrate, probe needles mounted the device substrate, a temperature sensor, and an active thermal management system thermally coupled to the first electronic tester device, the method comprising:
electrically connecting the ATE system to the DUT via the probe needles of the ATE system;
performing automated testing of the DUT by transmitting electrical signals to the DUT via the probe needles of the ATE system; and
during the automated testing of the DUT, actively cooling the first electronic tester device of the ATE system using the active thermal management system.

19. The method of claim 18, wherein actively cooling the first electronic tester device comprises:
using the temperature sensor to monitor a temperature indicative of the temperature of the first electronic tester device of the ATE system; and
when the temperature exceeds a first threshold temperature, activating the active thermal management system to cool the first electronic tester device of the ATE system.

20. The method of claim 19, wherein actively cooling the first electronic tester device further comprises:
when the temperature is less than a second threshold temperature, lower than the first threshold temperature, stopping the active cooling of the first device of the ATE system.
